(19) United States
(12) Patent Application Publication
(10) Pub. No.: US 2026/0063677 A1
(43) Pub. Date: Mar. 5, 2026

(54) CURRENT DETECTION APPARATUS

(71) Applicant: HONDA MOTOR CO., LTD., Tokyo (JP)

(72) Inventors: Kosuke KAJITA, Tokyo (JP); Shotaro KARASUYAMA, Tokyo (JP); Jiro FUKUI, Tokyo (JP); Satoshi HASHINO, Tokyo (JP)

(21) Appl. No.: 19/310,963

(22) Filed: Aug. 27, 2025

(30) Foreign Application Priority Data
Aug. 30, 2024 (JP) 2024-150188

(51) Int. Cl. G01R 15/14; G01R 19/00; G01R 33/00; G01R 33/02

(52) U.S. Cl. CPC G01R 15/148; G01R 19/0092; G01R 33/0005; G01R 33/0206

(57) ABSTRACT

A current detection apparatus includes an α-axis magnetic detection element 8α and a β-axis magnetic detection element 8β provided around the three busbars. A slit S extending in a width direction is formed on a V-phase busbar; a detection axis Oβ of the β-axis magnetic detection element 8β is arranged orthogonal to the width direction of the V-phase busbar 6v, on a β-axis element arrangement surface Pβ that is orthogonal to the V-phase busbar 6v and includes a detection center of the β-axis magnetic detection element 8β; and the detection center of the β-axis magnetic detection element 8β is arranged at a position that is in the center of the V-phase busbar 6v in the width direction and is offset from the slit S by a predetermined distance a along an extension direction of the V-phase busbar 6v when seen along the detection axis Oβ.

This application is based on and claims the benefit of priority from Japanese Patent Application No. 2024-150188, filed on 30 Aug. 2024, the content of which is incorporated herein by reference.

### BACKGROUND OF THE INVENTION

### Field of the Invention

The present invention relates to a current detection apparatus. More specifically, the present invention relates to a current detection apparatus for detecting a current of each phase of a three-phase motor based on two magnetic detection elements.

### Related Art

Recently, initiatives to realize a low-carbon or carbon-free society have been active, and, for vehicles, research and development for electric vehicles has been also carried out to reduce CO₂ emissions and improve energy efficiency.

As a method for controlling three-phase AC motors mounted on electric vehicles, home appliances (for example, air conditioners and washing machines), and the like, so-called vector control has been widely adopted. In the vector control, a motor control apparatus generates a command signal to an inverter, based on feedback control of a d-axis current and a q-axis current defined on d-q coordinates of a rotating Cartesian coordinate system of the motor.
Patent Document 1: PCT International Publication No. WO2013/058282
Patent Document 2: Chinese Patent Application CN202211040361.X

### SUMMARY OF THE INVENTION

Since feedback control of currents is performed on the d-q coordinates in the motor control apparatus as described above, it is necessary to convert, for example, the U-phase, V-phase, and W-phase currents of a motor detected by such a current detection apparatus as shown in Patent Document 1 to d-axis and q-axis currents. More specifically, in the motor control apparatus, after three phase currents (Iu, Iv, and Iw) detected by the current detection apparatus first are converted to two phase currents (Iα and Iβ) defined in a fixed coordinate system by the Clarke transformation, the two phase currents (Iα and Iβ) are converted to two phase currents (Id and Iq) defined in the d-q coordinate system by the Park transformation using a motor rotation angle θ. Thus, in the vector control using output of a conventional current detection apparatus, it is necessary to perform calculation for converting the three phase currents (Iu, Iv, and Iw) to the two phase currents (Id and Iq) in the motor control apparatus.

Furthermore, Patent Document 2 by the applicant of the present application describes a technology for, by providing two magnetic detection elements at geometrically determined positions around three phase current lines, trying to directly obtain two phase currents (Iα and Iβ) without performing the Clarke transformation by calculation by a computer (such a technology will be hereinafter also referred to as “spatial Clarke transformation”). According to the spatial Clarke transformation as above, it is possible to reduce the number of magnetic detection elements and reduce a calculation load on a computer in comparison with the conventional transformation.

In Patent Document 2, however, influence of positional deviation of the magnetic detection elements relative to each phase current line is not sufficiently considered. That is, in the spatial Clarke transformation technology shown in Patent Document 2, when the installation position of a magnetic detection element deviates from the initial ideal installation position, a relative position of the magnetic detection element relative to each phase current line also deviates, and, therefore, it is thought that the influence of the positional deviation is large.

An object of the present invention is to provide a current detection apparatus for three-phase motor with high toughness of magnetic detection elements against positional deviation relative to each phase current line and, therefore, contribute to improvement of energy efficiency.

(1) A current detection apparatus according to the present invention (for example, a current detection apparatus 3 described later) is a current detection apparatus for detecting currents flowing through a first phase busbar (for example, a U-phase busbar 6u described later), a second phase busbar (for example, a V-phase busbar 6v described later), and a third phase busbar (for example, a W-phase busbar 6w described later) of a three-phase motor (for example, a motor M described later), and the current detection apparatus including: an α-axis magnetic detection element (for example, an α-axis magnetic detection element 8α described later) and a β-axis magnetic detection element (for example, a β-axis magnetic detection element 8β described later) provided around the first, second, and third phase busbars, wherein a slit (for example, a slit S described later) extending in a width direction is formed on the second phase busbar; a detection axis (for example, a detection axis Oβ described later) of the β-axis magnetic detection element is arranged orthogonal to the width direction of the second phase busbar, on a β-axis element arrangement surface (for example, a β-axis element arrangement surface Pβ described later) that is orthogonal to the second phase busbar and includes a detection center of the β-axis magnetic detection element; and the detection center of the β-axis magnetic detection element is arranged at a position that is in a center of the second phase busbar in the width direction and is offset from the slit along an extension direction of the second phase busbar when seen along the detection axis of the β-axis magnetic detection element.

(2) In this case, it is preferable that the first, second, and third phase busbars are arranged on the β-axis element arrangement surface with the second phase busbar located in the middle, at equal intervals on a line along the width direction of the second phase busbar.

(3) In this case, it is preferable that an output value of the α-axis magnetic detection element is out of phase with an output value of the β-axis magnetic detection element by 90°.

(1) A current detection apparatus according to the present invention includes an α-axis magnetic detection element and a β-axis magnetic detection element provided around three busbars, and detects currents flowing through the three busbars based on output values of the two magnetic detection elements. Further, in the present invention, a detection axis of the β-axis magnetic detection element is arranged orthogonal to a width direction of a second phase busbar, on a β-axis element arrangement surface that is orthogonal to the second phase busbar and includes a detection center of the β-axis magnetic detection element, and the detection center of the β-axis magnetic detection element is arranged in the center of the second phase busbar in a width direction in plan view seen along the detection axis of the β-axis magnetic detection element. Thereby, the detection axis of the β-axis magnetic detection element is orthogonal to a magnetic field concentrically formed around the second phase busbar by a current flowing through the second phase busbar, on the β-axis element arrangement surface, and, therefore, it is possible to cause a magnetic sensitivity coefficient of the β-axis magnetic detection element for the second phase busbar to be 0. Here, when the detection center of the β-axis magnetic detection element deviates from the center of the second phase busbar in the width direction in plan view in a case where a current uniformly flows inside the second phase busbar along the width direction, the magnetic sensitivity coefficient of the β-axis magnetic detection element for the second phase busbar also deviates from zero. In comparison, in the present invention, a slit extending along the width direction is formed on the second phase busbar, and, furthermore, the detection center of the β-axis magnetic detection element is arranged at a position offset from the slit along an extension direction of the second phase busbar when seen in plan view. Thereby, as described later with reference to FIGS. 6A and 6B, it is possible to reduce the amount of variation of the magnetic sensitivity coefficient from zero due to deviation of the detection center of the β-axis magnetic detection element along the width direction. Therefore, according to the present invention, it is possible to improve toughness of the β-axis magnetic detection element against positional deviation along the width direction relative to the second phase busbar and, therefore, contribute to improvement of energy efficiency.

(2) In the present invention, the first, second, and third phase busbars are arranged on the β-axis element arrangement surface with the second phase busbar located in the middle, at equal intervals on a line along the width direction of the second phase busbar. Therefore, according to the present invention, since it is possible to cause the magnetic sensitivity coefficient of the β-axis magnetic detection element for the second phase busbar to be 0 while causing the absolute value of the magnetic sensitivity coefficient of the β-axis magnetic detection element for the first phase busbar and the absolute value of the magnetic sensitivity coefficient of the β-axis magnetic detection element for the third phase busbar to be equal, it is possible to cause the output value of the β-axis magnetic detection element to be proportional to a β-phase current value obtained by combining currents flowing through the first, second, and third phase busbars at a determined ratio by the Clarke transformation.

(3) In the present invention, the output value of the α-axis magnetic detection element is out of phase with the output value of the β-axis magnetic detection element by 90°. Therefore, according to the present invention, it is possible to cause the output values of the α-axis magnetic detection element and the β-axis magnetic detection element to be proportional to an α-phase current value and a β-phase current value which are obtained by combining currents flowing through the first, second, and third phase busbars at a determined ratio by the Clarke transformation.

### BRIEF DESCRIPTION OF THE DRAWINGS

FIG. 1 is a diagram showing a configuration of a current detection apparatus according to one embodiment of the present invention and an electric vehicle equipped with the current detection apparatus;

FIG. 2 is a diagram schematically showing a configuration of a sensor unit;

FIG. 3 is a diagram schematically showing an example of arrangement of the three busbars and an α-axis magnetic detection element on the α-axis element arrangement surface;

FIG. 4 is a diagram schematically showing an example of arrangement of the three busbars and the β-axis magnetic detection element on the β-axis element arrangement surface;

FIG. 5 is a diagram of a V-phase busbar and the β-axis magnetic detection element seen along a detection axis of the β-axis magnetic detection element;

FIG. 6A is a diagram showing distribution of components of magnetic flux density along the detection axis of the β-axis magnetic detection element, on a surface away from a surface of a part of the V-phase busbar where a slit is not formed, by a predetermined height; and

FIG. 6B is a diagram showing distribution of components of the magnetic flux density along the detection axis of the β-axis magnetic detection element, on the surface away from a surface of a part of the V-phase busbar where the slit is formed, by the predetermined height.

### DETAILED DESCRIPTION OF THE INVENTION

A description will be made below on a current detection apparatus according to one embodiment of the present invention and an electric vehicle mounted with the current detection apparatus with reference to drawings.

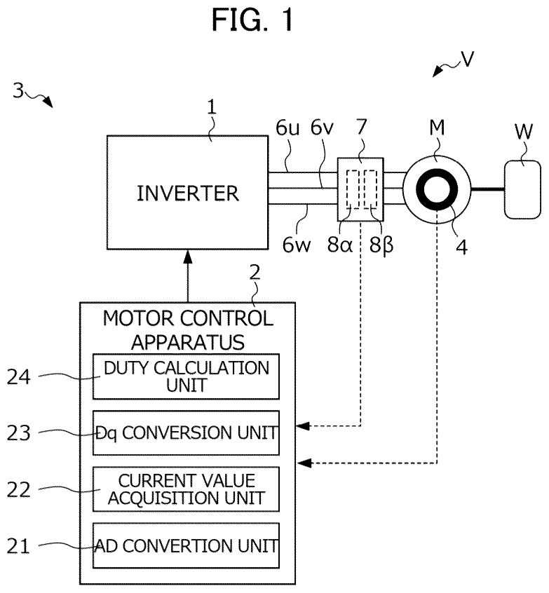

FIG. 1 is a diagram showing a configuration of a current detection apparatus 3 according to the present embodiment and an electric vehicle V equipped with the current detection apparatus 3. Note that, though the description will be made on the case where the current detection apparatus 3 is mounted on the electric vehicle V, the present invention is not limited thereto. The current detection apparatus 3 can be mounted on anything that controls the three-phase motor based on vector control, such as an air conditioner or a washing machine, in addition to the electric vehicle V.

The electric vehicle V includes a three-phase AC motor M (hereinafter simply referred to as “the motor M”), a drive wheel W coupled with the output shaft of the motor M via a power transmission mechanism not shown, an inverter 1 that connects a battery not shown and the motor M, a sensor unit 7 that generates a signal corresponding to a current that flows through the motor M, a resolver 4 that detects a rotation position of the motor M, and a motor control apparatus 2 that controls the inverter 1 based on detection signals of the sensor unit 7 and the resolver 4.

The inverter 1 is, for example, a PWM inverter using pulse width modulation, which is equipped with a bridge circuit configured by bridge connection of a plurality of switching elements (for example, IGBT's), and has a function of converting DC power and AC power. The inverter 1 is connected to the battery on the DC input/output side and connected to each of the U-phase, V-phase, and W-phase coils of the motor M on the AC input/output side, and converts power between the battery and the motor M. By performing on/off driving of the switching element of each phase according to a gate drive signal, which is generated from a gate drive circuit not shown at a predetermine timing, the inverter 1 converts DC power supplied from the battery to AC power to supply the AC power to the motor M or converts AC power supplied from the motor M to DC power to supply the DC power to the battery.

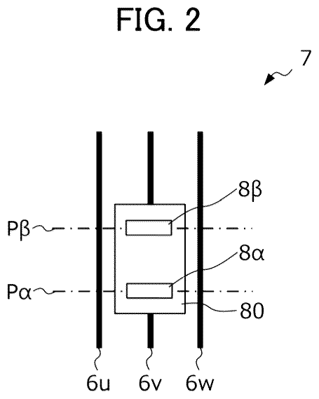

The sensor unit 7 includes an α-axis magnetic detection element 8α and a β-axis magnetic detection element 8β provided around three busbars (a U-phase busbar 6u, a V-phase busbar 6v, and a W-phase busbar 6w) that connect the motor M and the inverter 1. The magnetic detection elements 8α and 8β generate detection signals corresponding to components of the magnetic flux density of a magnetic field generated by currents flowing through the busbars 6u, 6v, and 6w, along their respective detection axes. Note that a specific example of arrangement of the α-axis and β-axis magnetic detection elements 8α and 8β, and the three busbars 6u, 6v, and 6w will be described later with reference to FIGS. 2 to 5.

The motor control apparatus 2 is a computer that generates a drive signal to the gate drive circuit of the inverter 1 by performing vector control based on detection signals from the two magnetic detection elements 8α and 8β and the resolver 4 and inputs the drive signal to the gate drive circuit.

In the motor control apparatus 2, an AD conversion unit 21, a current value acquisition unit 22, a dq conversion unit 23, and a duty calculation unit 24 are configured as modules related to execution of the vector control described above.

By performing AD conversion of detection signals of the α-axis and β-axis magnetic detection elements 8α and 8β, the AD conversion unit 21 acquires output values (S_{α} and S_{β}) of the α-axis and β-axis magnetic detection elements 8α and 8β.

Based on the output values (S_{α} and S_{β}) of the α-axis and β-axis magnetic detection elements 8α and 8β acquired by the AD conversion unit 21, the current value acquisition unit 22 acquires an α-phase current value I_{α} and a β-phase current value I_{β} corresponding to two phase currents, which are obtained by performing the Clarke transformation of three phase currents (Iu, Iv, and Iw) as shown by Formula (1-1) below. Note that, though, in the present embodiment, the description will be made on a case where the current value acquisition unit 22 acquires the output values (S_{α} and S_{β}) of the α-axis and β-axis magnetic detection elements 8α and 8β as α-phase and β-phase current values (I_{α}, I_{β}) as they are, as shown by Formula (1-2) below, the present invention is not limited thereto. For example, as described in Patent Application No. 2024-017417 by the applicant of the present application, the current value acquisition unit 22 may acquire values obtained by multiplying the output values (S_{α} and S_{β}) of the α-axis and β-axis magnetic detection elements 8α and 8β by predetermined α-phase and β-phase gains G_{α} and G_{β}, respectively, as the α-phase current value I_{α} and the β-phase current value I_{β}. Note that, in this case, values of the α-phase and β-phase gains (G_{α} and G_{β}) are set so that amplitudes of the α-phase and β-phase current values (I_{α}, I_{β}) are equal. Therefore, in the present embodiment, the current detection apparatus 3 that detects currents flowing through the three phase busbars 6u, 6v, and 6w of the motor M is configured with the two magnetic detection elements 8α and 8β, the AD conversion unit 21, and the current value acquisition unit 22.

$$( \begin{matrix}{I}_{α} \\ {I}_{β}\end{matrix} ) ∝ ( \begin{matrix}- 1 / 2 & 1 & - 1 / 2 \\ \sqrt{3} / 2 & 0 & - \sqrt{3} / 2\end{matrix} ) ( \begin{matrix}Iu \\ Iν \\ Iw\end{matrix} ) \qquad ( 1 - 1 )$$

$$( \begin{matrix}{I}_{α} \\ {I}_{β}\end{matrix} ) = ( \begin{matrix}{S}_{α} \\ {S}_{β}\end{matrix} ) \qquad ( 1 - 2 )$$

By performing known calculation using the current values (I_{α}, I_{β}) acquired by the current value acquisition unit 22 and a detection signal of the resolver 4, the dq conversion unit 23 calculates a d-axis current Id and a q-axis current Iq.

By acquiring a d-axis current command Idc and a q-axis current command Iqc corresponding to driving force required by a driver and performing feedback control based on deviations (Idc-Id, Iqc-Iq) of the current values, the duty calculation unit 24 generates a drive signal for the gate drive circuit of the inverter 1 so as to realize the driving force required by the driver and inputs the driving force to the gate drive circuit.

FIG. 2 is a diagram schematically showing a configuration of the sensor unit 7. The sensor unit 7 includes the α-axis magnetic detection element 8α and the β-axis magnetic detection element 8β provided around the three busbars 6u, 6v, and 6w, and a board 80 to which the magnetic detection elements 8α and 8β are fixed. That is, the two magnetic detection elements 8α and 8β are arranged around the three busbars 6u, 6v, and 6w in a state of being integrated by the board 80. Further, the description will be made below on a case where, as shown in FIG. 2, the detection center of the α-axis magnetic detection element 8α is arranged within a virtual α-axis element arrangement surface Pα that is orthogonal to the three busbars 6u, 6v, and 6w, and the detection center of the β-axis magnetic detection element 8β is arranged within a virtual β-axis element arrangement surface Pβ that is orthogonal to the three busbars 6u, 6v, and 6w and is different from the α-axis element arrangement surface Pα described above. The present invention, however, is not limited thereto. The α-axis element arrangement surface Pα and the β-axis element arrangement surface Pβ may be a common virtual surface. In other words, the detection centers of the α-axis magnetic detection element 8α and the β-axis magnetic detection element 8β may be provided within a common element arrangement surface that is orthogonal to the three busbars 6u, 6v, and 6w.

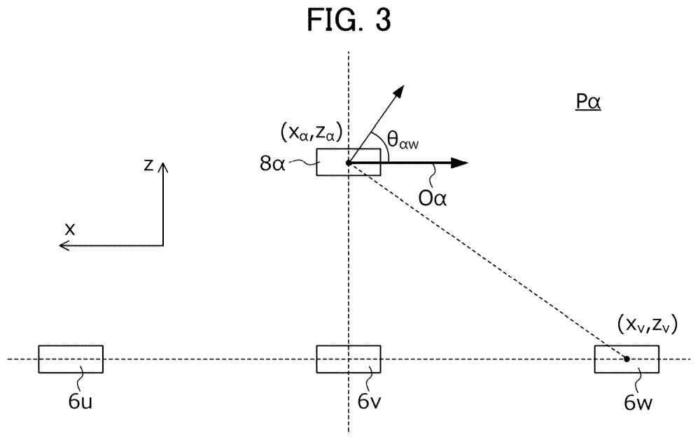

FIG. 3 is a diagram schematically showing an example of arrangement of the three busbars 6u, 6v, and 6w and the α-axis magnetic detection element 8α on the α-axis element arrangement surface Pα. Note that, though FIG. 3 shows a case where the three busbars 6u, 6v, and 6w are linearly arranged in order of the U-phase busbar 6u, the V-phase busbar 6v, and the W-phase busbar 6w, at equal intervals within the α-axis element arrangement surface Pα, the present invention is not limited thereto. When the three busbars 6u, 6v, and 6w are arranged as above, a detection axis Ox of the α-axis magnetic detection element 8α is arranged parallel to a virtual line that passes through the three busbars 6u, 6v, and 6w as shown in FIG. 3. Furthermore, the detection center of the α-axis magnetic detection element 8α is arranged at a predetermined position on a virtual line that is orthogonal to a virtual line passing through the three busbars 6u, 6v, and 6w and passes through the V-phase busbar 6v in the middle as shown in FIG. 3. Note that, hereinafter, the description will be made on a case where the three busbars 6u, 6v, and 6w are rectangular and plate-shaped, extending in the extension direction when seen in sectional view, as shown in FIGS. 2 and 3.

Here, the output value S_{α} of the α-axis magnetic detection element 8α is expressed by Formula (2-1) below when magnetic sensitivity coefficients (k_{αu}, k_{αv}, and k_{αw}) of the α-axis magnetic detection element 8α for the busbars 6u, 6v, and 6w, respectively, are used. The magnetic sensitivity coefficients (k_{αu}, k_{αv}, and k_{αw}) are values determined by relative positions relative to the three busbars 6u, 6v, and 6w of the α-axis magnetic detection element 8α, respectively, and the direction of the detection axis. More specifically, for example, the magnetic sensitivity coefficient k_{αw} of the α-axis magnetic detection element 8α for the W-phase busbar 6w is defined by Formula (2-2) below according to Ampere's Law. In Formula (2-2) below, μ represents magnetic permeability. Furthermore, in Formula (2-2) below, θ_{wα} indicates an angle formed by a magnetic field vector of the W-phase busbar 6w and the detection axis of the α-axis magnetic detection element 8x, (x_{α}, z_{α}) indicates coordinate values of the α-axis magnetic detection element 8α on the α-axis element arrangement surface Pα; and (x_{w}, z_{w}) indicates coordinate values of the W-phase busbar 6w on the α-axis element arrangement surface Pα. Note that, since the other magnetic sensitivity coefficients (k_{αu} and k_{αw}) are also defined based on Ampere's Law similarly to Formula (2-2) below, detailed description thereof will be omitted. As described above, the magnetic sensitivity coefficients (k_{αu}, k_{αv}, and k_{αw}) are determined by relative positions relative to the three busbars 6u, 6v, and 6w of the α-axis magnetic detection element 8α and the direction of the detection axis.

$${S}_{α} ∝ [ {k}_{au} {k}_{av} {k}_{aw} ] [ \begin{matrix}{I}_{u} \\ {I}_{v} \\ {I}_{w}\end{matrix} ] \qquad ( 2 - 1 )$$

$${k}_{α w} = \frac{μ cos {θ}_{α w}}{2 π \sqrt{{( {x}_{w} - {x}_{α} )}^{2} + {( {z}_{w} - {z}_{α} )}^{2}}} \qquad ( 2 - 2 )$$

Furthermore, the detection center of the α-axis magnetic detection element 8α is arranged at such a position that Formula (3) below for the magnetic sensitivity coefficients (k_{αu}, k_{αv}, and k_{αw}) holds on the α-axis element arrangement surface Pα. Thereby, it is possible to cause the output value S_{α} of the α-axis magnetic detection element 8α to be proportional to the α-phase current values I_{α}.

$$[ \begin{matrix}{k}_{α u} \\ {k}_{α v} \\ {k}_{α w}\end{matrix} ] ∝ [ \begin{matrix}- 1 / 2 \\ 1 \\ - 1 / 2\end{matrix} ] \qquad ( 3 )$$

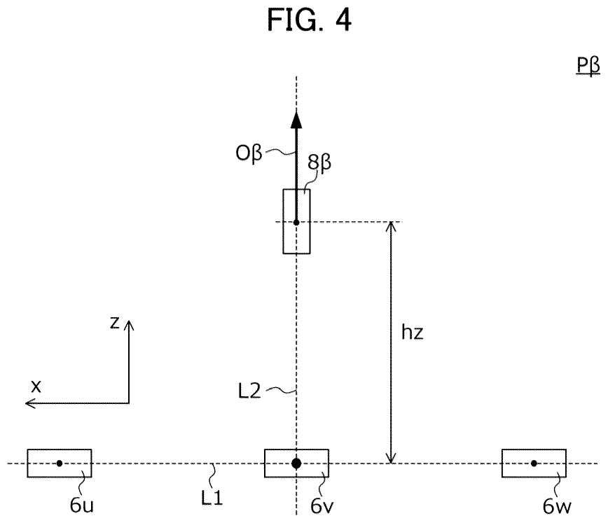

FIG. 4 is a diagram schematically showing an example of arrangement of the three busbars 6u, 6v, and 6w and the β-axis magnetic detection element 8β on the β-axis element arrangement surface Pβ.

As shown in FIG. 4, the U-phase busbar 6u, the V-phase busbar 6v, and the W-phase busbar 6w are arranged on the β-axis element arrangement surface Pβ at equal intervals with the V-phase busbar 6v in the middle, on a straight line along the width direction of the plate-shaped V-phase busbar 6v. More specifically, within the β-axis element arrangement surface pp, the three busbars 6u, 6v, and 6w are arranged at equal intervals in order of the U-phase busbar 6u, the V-phase busbar 6v, and the W-phase busbar 6w, on a first virtual line L1 that is parallel to the width direction of the three busbars 6u, 6v, and 6w and passes through the centers of the busbars 6u, 6v, and 6w.

As shown in FIG. 4, a detection axis Oβ of the β-axis magnetic detection element 8β is arranged orthogonal to the width direction of the V-phase busbar 6v on the β-axis element arrangement surface Pβ. More specifically, within the β-axis element arrangement surface Pβ, the detection center of the β-axis magnetic detection element 8β is arranged on a second virtual line L2 that is orthogonal to the first virtual line L1 described above and passes through the center of the V-phase busbar 6v in the middle in the width direction. Further, the detection axis Oβ of the β-axis magnetic detection element 8β is arranged parallel to the second virtual line L2. Thereby, it is possible to cause the magnetic sensitivity coefficient of the β-axis magnetic detection element 8β for the V-phase busbar 6v to be 0 while causing the absolute value of the magnetic sensitivity coefficient of the β-axis magnetic detection element 8β for the U-phase busbar 6u and the absolute value of the magnetic sensitivity coefficient of the β-axis magnetic detection element 8β for the W-phase busbar 6w to be equal. Thereby, it is possible to cause an output value S_{β} of the β-axis magnetic detection element 8β to be proportional to the β-phase current value I_{β} which is out of phase with the α-phase current value I_{α} by 90° as shown by Formula (4) below. Note that, hereinafter, a distance between the detection center of the β-axis magnetic detection element 8β and the center of the V-phase busbar 6v along the second virtual line L2 on the β-axis element arrangement surface Pβ will be referred to as height of the β-axis magnetic detection element 8β relative to the V-phase busbar 6v and will be indicated by “hz”.

$${S}_{β} ∝ [ \sqrt{3} / 2 \begin{matrix}0 & - \sqrt{3} / 2 ] & [ \begin{matrix}{I}_{u} \\ {I}_{v} \\ {I}_{w}\end{matrix} ]\end{matrix} \qquad ( 4 )$$

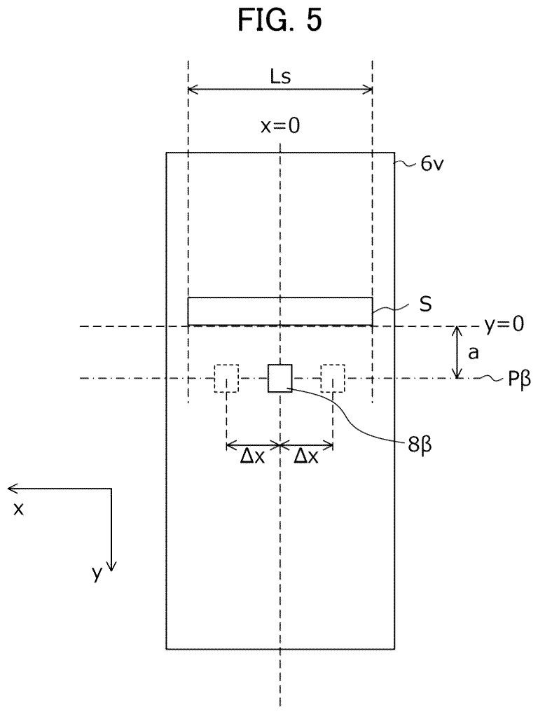

FIG. 5 is a diagram of a V-phase busbar 6v and the β-axis magnetic detection element 8β seen along the detection axis Oβ of the β-axis magnetic detection element 8β.

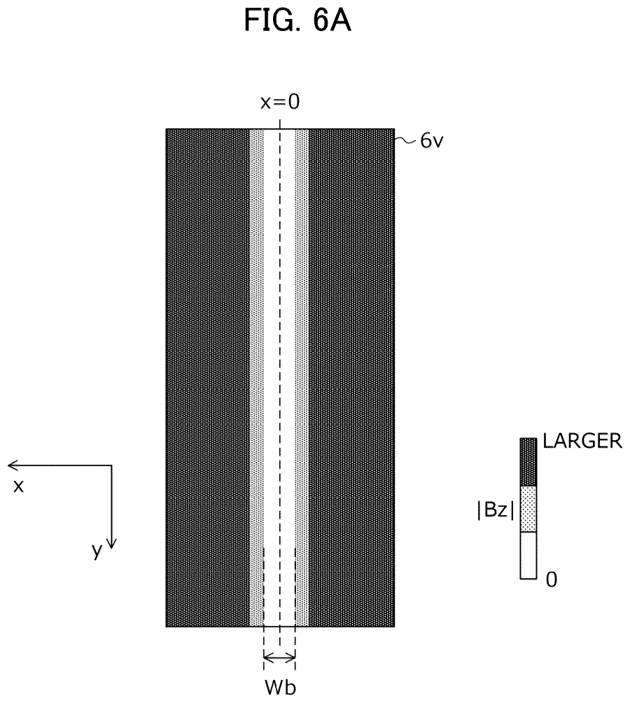

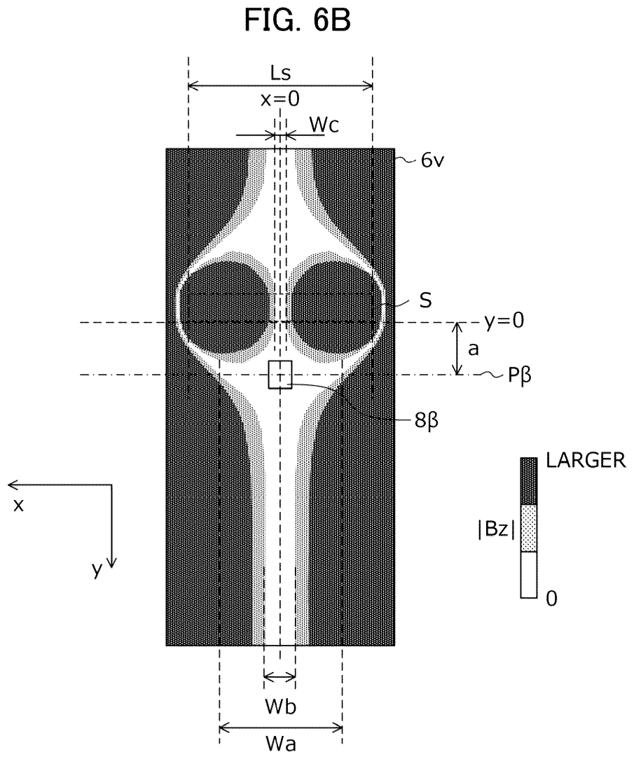

In the center of the V-phase busbar 6v in the width direction, a slit S extending in the width direction is formed. Here, as shown in FIG. 5, the slit S is rectangular when seen from the detection axis Oβ of the β-axis magnetic detection element 8β. Furthermore, as shown in FIG. 5, the detection center of the β-axis magnetic detection element 8β is arranged at a position that is in the center of the V-phase busbar 6v in the width direction (a position of x=0 in FIG. 5) and is offset from an end part of the slit S (a position of y=0 in FIG. 5) by a predetermined distance a along the extension direction of the V-phase busbar 6v when seen along the detection axis Oβ of the β-axis magnetic detection element 8β. Here, a length Ls along the width direction of the slit S is determined, for example, based on an allowable installation error Δx along the width direction of the β-axis magnetic detection element 8β as described later with reference to FIGS. 6A and 6B.

Each of FIGS. 6A and 6B is a diagram showing distribution of components of magnetic flux density along the detection axis Oβ, on a surface away from the surface of the V-phase busbar 6v by a predetermined height hz (hereinafter simply referred to as the magnetic flux density Bz). More specifically, FIG. 6A shows distribution of the magnetic flux density Bz generated around a part of the V-phase busbar 6v where the slit S is not formed, and FIG. 6B shows distribution of the magnetic flux density Bz generated around a part of the V-phase busbar 6v where the slit S is formed. Note that, in FIGS. 6A and 6B, the magnetic flux density Bz is shown in darker color as the absolute value thereof is larger.

As shown in FIG. 6A, on the part of the plate-shaped V-phase busbar 6v where the slit S is not formed, the magnitude and direction of the current density is almost uniform along the width direction of the V-phase busbar 6v. Therefore, the absolute value of the magnetic flux density Bz on the surface away from the V-phase busbar 6v by the height hz, where the β-axis magnetic detection element 8β is arranged, is 0 in the center of the V-phase busbar 6v in the width direction (the position of x=0 in FIG. 6A). Furthermore, the further away from the center in the width direction is, the larger the absolute value is. Therefore, as the detection center of the β-axis magnetic detection element 8β is further away from the center of the V-phase busbar 6v in the width direction, the magnetic flux density Bz by the V-phase busbar 6v influences the output value S_{β} of the β-axis magnetic detection element 8β more.

In comparison, as shown in FIG. 6B, the magnitude and direction of the current density is not uniform along the width direction of the V-phase busbar 6v near the part where the slit S is formed on the plate-shaped V-phase busbar 6v. Therefore, the distribution of the magnetic flux density Bz on the surface away from the V-phase busbar 6v by the height hz differs between the part near the slit S and the part away from the slit S. More specifically, the length of an area where the absolute value of the magnetic flux density Bz is approximately 0 (in other words, an area where the absolute value of the magnetic flux density Bz is equal to or below a threshold set to a value that is slightly larger than 0 and which is shown in white in FIGS. 6A and 6B) along the width direction (hereinafter also referred to as “the deadband width”) differs between the part near the slit S and the part away from the slit S. More specifically, as shown in FIGS. 6A and 6B, the length of a deadband width Wa at the position offset from the end part of the slit S by the predetermined distance a along the extension direction of the V-phase busbar 6v is the longest, being followed by the length of a deadband width Wb at a position sufficiently away from the slit S and then the length of a deadband width Wc directly above the slit S (Wa>Wb>Wc). Thus, by forming the slit S on the V-phase busbar 6v and arranging the detection center of the β-axis magnetic detection element 8β at the position offset from the end part of the slit S by the distance a determined according to the shape of the slit S, along the extension direction of the V-phase busbar 6v when seen along the detection axis Oβ as described above, it is possible to improve toughness of the β-axis magnetic detection element 8β against positional deviation along the width direction relative to the V-phase busbar 6v more than the case of arranging the detection center of the β-axis magnetic detection element 8β directly above the slit S or at a position sufficiently away from the slit S.

As shown in FIG. 6B, it is thought that, when the length Ls along the width direction of the slit S is increased, the deadband width also increases. Therefore, the length Ls along the width direction of the slit S is set to a length according to the allowable installation error Δx along the width direction of the β-axis magnetic detection element 8β. More specifically, the length Ls along the width direction of the slit S is set, for example, to a length larger than twice the allowable installation error Δx (that is, Ls>2Δx).

Furthermore, it is thought that a position at which the deadband width becomes the largest correlates with the length Ls along the width direction of the slit S as shown in FIG. 6B. Therefore, the distance a relative to the arrangement position of the detection center of the β-axis magnetic detection element 8β is determined, for example, based on the length Ls along the width direction of the slit S.

According to the current detection apparatus 3 according to the present embodiment, the following effects are obtained:

(1) The current detection apparatus 3 includes the α-axis magnetic detection element 8α and the β-axis magnetic detection element 8β provided around the three busbars 6u, 6v, and 6w, and detects currents I_{α} and I_{β} flowing through the three busbars 6u, 6v, and 6w based on the output values Sa and S_{β} of the two magnetic detection elements 8α and 8β. Further, in the current detection apparatus 3, the detection axis Oβ of the β-axis magnetic detection element 8β is arranged orthogonal to the width direction of the V-phase busbar 6v, on the β-axis element arrangement surface Pβ that is orthogonal to the V-phase busbar 6v and includes the detection center of the β-axis magnetic detection element 8β, and the detection center of the β-axis magnetic detection element 8β is arranged in the center of the V-phase busbar 6v in the width direction in plan view seen along the detection axis Oβ of the β-axis magnetic detection element 8β. Thereby, the detection axis Oβ of the β-axis magnetic detection element 8β is orthogonal to a magnetic field concentrically formed around the V-phase busbar 6v by a current flowing through the V-phase busbar 6v, on the β-axis element arrangement surface Pβ, and, therefore, it is possible to cause the magnetic sensitivity coefficient of the β-axis magnetic detection element 8β for the V-phase busbar 6v to be 0. Here, when the detection center of the β-axis magnetic detection element 8β deviates from the center of the V-phase busbar 6v in the width direction in plan view in a case where a current uniformly flows inside the V-phase busbar 6v along the width direction, the magnetic sensitivity coefficient of the β-axis magnetic detection element for 8β for the V-phase busbar 6v also deviates from zero. In comparison, in the current detection apparatus 3, the slit S extending along the width direction is formed on the V-phase busbar 6v, and, furthermore, the detection center of the β-axis magnetic detection element 8β is arranged at a position offset from the slit S along the extension direction of the V-phase busbar 6v when seen in plan view. Thereby, it is possible to reduce the amount of variation of the magnetic sensitivity coefficient from zero due to deviation of the detection center of the β-axis magnetic detection element 8β along the width direction. Therefore, according to the current detection apparatus 3, it is possible to improve toughness of the β-axis magnetic detection element 8β against positional deviation along the width direction relative to the V-phase busbar 6v and, therefore, contribute to improvement of energy efficiency.

(2) The three busbars 6u, 6v, and 6w are arranged on the β-axis element arrangement surface Pβ with the V-phase busbar 6v located in the middle, at equal intervals on a line along the width direction of the V-phase busbar 6v. Therefore, according to the current detection apparatus 3, since it is possible to cause the magnetic sensitivity coefficient of the β-axis magnetic detection element 8β for the V-phase busbar 6v to be 0 while causing the absolute value of the magnetic sensitivity coefficient of the β-axis magnetic detection element 8β for the U-phase busbar 6u and the absolute value of the magnetic sensitivity coefficient of the β-axis magnetic detection element 8β for the W-phase busbar 6w to be equal, it is possible to cause the output value of the β-axis magnetic detection element 8β to be proportional to the β-phase current value I_{β} obtained by combining currents flowing through the busbars 6u, 6v, and 6w at a determined ratio by the Clarke transformation.

(3) In the current detection apparatus 3, the output value S_{α} of the a-axis magnetic detection element 8α is out of phase with the output value of the β-axis magnetic detection element 8β by 90°. Therefore, according to the current detection apparatus 3, it is possible to cause the output values S_{α} and S_{β} of the α-axis magnetic detection element 8α and the β-axis magnetic detection element 8β to be proportional to the α-phase current value I_{α} and the β-phase current value I_{β} which are obtained by combining currents flowing through the busbars 6u, 6v, and 6w at a determined ratio by the Clarke transformation.

Though one embodiment of the present invention has been described above, the present invention is not limited thereto. A detailed configuration may be appropriately changed within the spirit of the present invention.

What is claimed is:

1. A current detection apparatus for detecting currents flowing through a first phase busbar, a second phase busbar, and a third phase busbar of a three-phase motor, the current detection apparatus comprising:
an α-axis magnetic detection element and a β-axis magnetic detection element provided around the first, second, and third phase busbars, wherein
a slit extending in a width direction is formed on the second phase busbar;
a detection axis of the β-axis magnetic detection element is arranged orthogonal to the width direction of the second phase busbar, on a β-axis element arrangement surface that is orthogonal to the second phase busbar and includes a detection center of the β-axis magnetic detection element; and
the detection center of the β-axis magnetic detection element is arranged at a position that is in a center of the second phase busbar in the width direction and is offset from the slit along an extension direction of the second phase busbar when seen along the detection axis of the β-axis magnetic detection element.

2. The current detection apparatus according to claim 1, wherein the first, second, and third phase busbars are arranged on the β-axis element arrangement surface with the second phase busbar located in middle, at equal intervals on a line along the width direction of the second phase busbar.

3. The current detection apparatus according to claim 2, wherein an output value of the α-axis magnetic detection element is out of phase with an output value of the β-axis magnetic detection element by 90°.
